(19) United States
(12) Patent Application Publication
(10) Pub. No.: US 2023/0223166 A1
(43) Pub. Date: Jul. 13, 2023

(54) HIGH DIELECTRIC FILMS AND SEMICONDUCTOR OR CAPACITOR DEVICES COMPRISING SAME

(71) Applicant: The Industry & Academic Cooperation in Chungnam National University (IAC), Daejeon (KR)

(72) Inventors: Eui-Tae KIM, Daejeon (KR); Dong-Ok KIM, Daejeon (KR)

(73) Assignee: The Industry & Academic Cooperation in Chungnam National University (IAC), Daejeon (KR)

(21) Appl. No.: 18/008,851

(22) PCT Filed: Jun. 11, 2021
(86) PCT No.: PCT/KR2021/007349

§ 371 Date: Dec. 7, 2022

(30) Foreign Application Priority Data
Jun. 12, 2020 (KR) 10-2020-0071703

(51) Int. Cl. H01B 3/18; H01J 37/32; H01L 21/02; H01L 29/94; H01L 29/51; H01G 4/14; C23C 16/26; C23C 16/50; C23C 16/52

(52) U.S. Cl. CPC H01B 3/18; H01J 37/321; H01J 37/32522; H01J 37/32449; H01J 37/32816; H01L 21/02274; H01L 21/02115; H01L 29/94; H01L 29/51; H01L 28/40; H01G 4/145; C23C 16/26; C23C 16/50; C23C 16/52; H01J 2237/3321; H01J 2237/182

(57) ABSTRACT

There is provided a high dielectric film including amorphous hydrocarbon of which a dielectric constant is 10 or more. A leakage current of the high dielectric film is 1 A/cm² or less, and an insulation level is 1 MV/cm or more. Rms surface roughness of the high dielectric film is 20 nm or less.

### CROSS-REFERENCE TO PRIOR APPLICATIONS

This application is a National Stage Patent Application of PCT International Patent Application No. PCT/KR2021/007349 (filed on Jun. 11, 2021) under 35 U.S.C. § 371, which claims priority to Korean Patent Application No. 10-2020-0071703 (filed on Jun. 12, 2020), which are all hereby incorporated by reference in their entirety.

### BACKGROUND

The present disclosure relates to new high dielectric films and semiconductor or capacitor devices including the high dielectric films, wherein the high dielectric films are useful in manufacturing highly integrated devices because of their high dielectric constant, low leakage current, and high dielectric strength.

Integration of high-density semiconductor devices, such as memory devices or logic devices, needs high dielectric films having a high dielectric constant(high-k), a low leakage current, and a high dielectric strength. For example, a gate length of a MOSFET transistor has significantly reduced from 10 μm to 10 nm over the last few decades. Accordingly, utility of a SiO₂ thin film used as a conventional insulation film reached its limit. A material having a higher dielectric constant than 3.9 of a dielectric constant of SiO₂ is generally referred to as a high dielectric. Therefore, developments of a new high dielectric material having a higher permittivity than that of SiO₂ is active. As a high dielectric material, Ta₂O₄ or Al₂O₃, and the like applied in the early days, and Hf- or Zr-based oxides recently receive extensive attention with respect to 100 nm or less nodes. At present, studies are proceeded in various directions such as a method of finding substitutes (Al, Zr, Ta, STO, BST, and the like) for a Hf Source and a method of adding other materials to a Hf Source and depositing it. These high dielectrics may mostly apply to a device in a form of a high dielectric film, which is an oxide thin film. However, a high dielectric layer of metal oxides includes many bulk traps such as an oxygen vacancy, increases CV hysteresis, and results in an instability phenomenon of threshold voltage. Also, if a node size of a device is reduced to a 10 nm unit, 1 nm or less of an equivalent oxide thickness is needed. In the relevant condition, electron tunneling of Hf- or Zr-based oxides may occur. Moreover, Hf- or Zr-based oxides are easily crystallized, and thus a high leakage current is exhibited, and interfacial properties are deteriorated. Therefore, developments of a new high dielectric film are required for technologies having 10 nm or less nodes.

A carbon thin film receives much attention in technical and industrial application fields due to excellent electrical and mechanical properties. Carbon-based materials forming a carbon thin film may be classified into diamond, graphene, and amorphous carbon depending on bonding. It is known that bonding of carbon-based materials may be controlled by a deposition condition, in particular, temperature control. For example, according to Chemical Vapor Deposition(CVD) widely used for manufacturing a carbon-based thin film, high-quality graphene and carbon nanotube are manufactured at a high temperature of ˜1000° C. If a deposition temperature is lowered to about ˜700° C., a nanographite structure is formed. At room temperature, amorphous carbon is formed. In diamond where a carbon atom has the strongest sp³ bond with surrounding 4 carbon atoms, its hardness is very high but there is no electrical conductivity at all. Graphene has the sp² bond with surrounding 3 carbon atoms and has a 2-dimensional n-conjugation structure, and thus electron mobility is very high as 25000 cm²/V-s and conductivity is excellent. Amorphous carbon has all of a sp³ bond and a sp² bond, and thus its conductivity is low compared to that of graphene.

Studies about carbon-based materials focus on studies about a nanostructure having a highly aligned structure such as graphene and carbon nanotube having high potentiality as a transparent conductor or a next-generation semiconductor thanks to high conductivity properties and transparency. Compared to the above, amorphous carbon did not receive much attention even though it also exhibits various interesting properties. Amorphous carbon contains a called “dangling bond”, which means a fixed free radical, in a large percentage, and thus it may be processed under a proper condition to develop materials having various properties. However, identically to amorphous carbon, tries to utilize it for developing and applying materials having new properties were very limited.

By using nature that an amorphous hydrocarbon film is easy to form an even thin film having a uniform thickness, is excellent for interfacial bonding with an organic layer and an inorganic layer, and has a low dielectric property, the amorphous hydrocarbon film has used as an etching mask (Korean publication patent No. 10-2010-0112070, Korean registration patent No. 10-1837370), has used as a protective film of an insulation film(Korean publication patent No. 10-2013-0108611), and has used for preventing thin film defects and increasing interlayer adherency as a low dielectric insulator such as an interlayer material of semiconductor metal wiring(Korean registration patent No. 10-0850495). However, an example that an amorphous hydrocarbon film is used as a high dielectric film has not been reported still now.

### SUMMARY

To solve problems of the conventional technologies, the present disclosure is directed to provide new high dielectric films which are useful for manufacturing very large-scale integration devices because of their high dielectric constant, low leakage current, and high dielectric strength.

The present disclosure is also directed to provide semiconductor and capacitor devices which include the high dielectric film and exhibit excellent performance.

To achieve the above objectives, the present disclosure relates to high dielectric films having a feature of including amorphous hydrocarbon of which a dielectric constant is 10 or more.

An amorphous hydrocarbon thin film is easy to form an even thin film having a uniform thickness, has a high level, and has excellent interfacial bonding with not only an organic layer but also an inorganic layer. However, it has been only known to have a low dielectric property in the conventional technologies. The present disclosure confirms that an amorphous hydrocarbon thin film having a high dielectric property of which a dielectric constant is 10 or more may be manufactured and has a feature to provide a high dielectric film using the same.

In advance, in whole specification, unless explicitly described to the contrary, when any part “comprises” any component, it means to imply the inclusion of stated components but not exclusion of any other components. Further, when a part such as a layer, film, region, or substrate is referred to as being “over”, “on”, or “upper” another part, it can be “directly on” the other part or intervening parts may be also present. In contrast, when a part is referred to as being “directly on” another part, there are no intervening parts present. In the same way, when a part such as a layer, film, region, or substrate is referred to as being “under”, “below”, or “lower” another part, it may be “directly below” the other part or intervening parts may be also present. In contrast, when a part is referred to as being “directly below” another part, there are no intervening parts present. Also, when any part is formed “overall” on another part, it may be formed on a whole surface of another part or it may not be formed on one part of an edge.

In drawings of the present disclosure, for convenience of explanation, thicknesses of some layers and regions may be exaggerated to clearly present a number of layers and regions.

It was confirmed that high dielectric films of the present disclosure had an amorphous structure in a TEM image and a Raman spectrum and was formed of amorphous hydrocarbon including sp³ bonding of carbon-hydrogen via XPS, FTIR, and secondary ion mass spectrometry. Also, there was no peak change in an XPS spectrum and a secondary ion mass spectrometry spectrum observed while etching with Ar⁺ plasma, so that it could be confirmed that a composition of High dielectric film were uniform.

The dielectric constant of high dielectric films of the present disclosure may be 10 or more, preferably 20 to 200, and more preferably 30 to 150. High dielectric films of the present disclosure may realize significantly high dielectric properties compared to a dielectric constant of hafnium (Hf) or zirconium (Zr) oxides known as high dielectric oxides of conventional technologies. Therefore, it is expected that it may usefully apply to a semiconductor having a node of 10 nm or less.

High dielectric films of the present disclosure may have 1 A/cm² or less of a leakage current and 1 MV/cm or more of an insulation level, and preferably 0.5 A/cm² or less of a leakage current and 5 MV/Cm of an insulation level. The high dielectric film manufactured in the following examples has 0.25 A/cm² or less of a leakage current and 5 MV/cm or more of an insulation level in an equivalent oxide film thickness of 0.2 nm and exhibits excellent properties compared to Hf- or Zr-based oxides such as HfO₂, ZrO₂, HfAlO^{x}, or ZrAlOₓ known as conventional high dielectric oxides.

High dielectric films of the present disclosure have rms surface roughness of 20 nm or less, preferably 10 nm or less, and more preferably 5 nm or less. As surface roughness is lowered, an interfacial defect is also lowered and excellent interfacial properties are exhibited. Therefore, there is no meaning in setting its the lowest limit. High dielectric layers of metal oxides include many bulk traps such as an oxygen vacancy, increases CV hysteresis, and results in an instability phenomenon of threshold voltage. On the contrary, High dielectric films of the present disclosure are possible to be grown as a very uniform and smooth structure of which surface roughness is very low and in which there is no pin hole depending on deposition conditions and thicknesses of thin films. High dielectric films manufactured in the following examples have nearly no defect on an interface, so that it may be confirmed that it exhibits stable properties that there is no CV hysteresis or flat band voltage shift.

High dielectric films of the present disclosure may be manufactured by including steps of (A) positioning a substrate within a plasma reactor; (B) injecting a first gas including a hydrocarbon gas and a second gas including a hydrogen gas into the reactor; and (C) generating plasma within the reactor, thereby growing a hydrocarbon thin film, wherein at least one of a temperature, a pressure, a flow rate of the first gas, a flow rate of the second gas, and plasma intensity of the reactor is controlled in order that the hydrocarbon thin film is the hydrocarbon thin film having a dielectric constant of 10 or more.

According to the present disclosure, the plasma reactor is to generate plasma within a reactor and induce reaction of a reaction gas. For example, there are plasma-assisted chemical vapor deposition (PE-CVD) or inductively coupled plasma chemical vapor deposition (ICP-CVD), electron cyclotron resonance chemical vapor deposition (ECR-CVD) reactors. Plasma generates many radicals having high reaction from a reaction gas and thus it is possible to form a thin film even at a low temperature. In the following examples, ICP-CVD is explained as an example but it is natural that it is not limited.

According to the present disclosure, a substrate has a role of a basic material for forming a high dielectric film thereon, wherein any substrate used for generally manufacturing a thin film may be used. For example, there are silicon, glass, metal, and metal oxide substrates, wherein an additional catalyst layer is not necessary. The substrate includes not only a substrate for manufacturing a semiconductor device but also a substrate on which an active layer is formed in general. The substrate may be variously designed according to its use and purpose of a semiconductor device to which the substrate applies.

Before the step(A), a step of washing the substrate may be further included. Via the step of washing the substrate, a surface state useful for directly growing a hydrocarbon thin film may be implemented. The step of washing the substrate may be performed by a step of washing a surface of the substrate using, for example, hydrofluoric acid solution. In an embodiment, the hydrofluoric acid solution may be hydrofluoric acid solution including about 5 wt % to 20 wt % of hydrofluoric acid.

As a reaction gas, the first gas includes a hydrocarbon gas, wherein any one which may form a hydrocarbon thin film with plasma may be used as the hydrocarbon gas. In general, it is possible to use one or more selected from the group of methane, ethane, propane, ethylene, acetylene, propylene, and benzene which may be used for manufacturing graphene by a chemical vapor deposition at a high temperature. The first gas may include an inert gas besides a hydrocarbon gas. However, other hydrocarbon gases are not excluded.

The second gas includes a hydrogen gas, and an inert gas may be additionally included besides the hydrogen gas.

Besides the first and second gases, inert gases such as argon or helium may be further included as a transfer gas.

Properties of a hydrocarbon thin film forming a high dielectric film are determined by a temperature, a pressure, a flow rate of the first gas, a flow rate of the second gas, and plasma intensity of a reactor, wherein an amorphous hydrocarbon thin film of which a dielectric constant is 10 or more may be grown by controlling each parameter. Accordingly, each parameter is specifically described. It is natural that an optimized absolute value of each parameter may be changed depending on each equipment. Referring to the following description to the parameters, it is easy to manufacture a thin film having a thickness, a dielectric constant, and surface roughness which are proper for use to be used.

It is already well known that when plasma applies under a mixture gas of a hydrocarbon gas and a hydrogen gas, a hydrocarbon thin film is formed on a substrate, wherein a high-quality graphene thin film is formed at a high temperature, and as a temperature is lowered, crystallizability of a graphene thin film is degraded. As confirmed in the following examples, in manufacturing a high dielectric film of the present disclosure, properties of a generated thin film were changed depending on a thin film growth temperature. When other conditions were the same upon depositing, graphene was formed at a high temperature. As a temperature was lowered, nanographite including nano graphene crystals was formed within an amorphous hydrocarbon thin film. When a thin film manufacturing temperature was more lowered, a high dielectric film of the present disclosure which was formed of a hydrocarbon thin film of which a dielectric constant was 10 or more was formed. When a temperature was far more lowered than the above, a low dielectric (low-k) hydrocarbon thin film was formed. Under a specific condition of the following examples, a hydrocarbon manufactured at 200˜600° C. exhibited a high dielectric property but it may be changed according to equipment to be used, reaction conditions, and a type of a substrate. Therefore, it may be properly controlled to exhibit a desired dielectric constant in a range of 20˜700° C.

A pressure within the reactor is preferably 0.1 Torr-10 Torr in order that plasma discharge may be smoothly done. If a pressure is too high, plasma maintenance is difficult, and thus hydrocarbon thin film deposition efficiency may be lowered. If the pressure is too low, a process efficiency may be degraded.

According to the present disclosure, in order to induce a dangling bond and a hydrogen bond increasing within a thin film, as a thin film manufacturing temperature is lowered, a mixture of a hydrocarbon gas and a hydrogen gas is used as a reaction gas. In the step (B), a volume ratio of the hydrocarbon gas of the first gas and the hydrogen gas of the second gas is preferably about 100:1˜1:50. If a ratio of the hydrogen gas is too low, a surface of a thin film is rough, and thus a surface property may be degraded. If it is too high, a hydrocarbon thin film is not formed well.

In the present disclosure, plasma intensity also affects a dielectric constant of a high dielectric film. Plasma intensity may be controlled in a range of 100 W˜1,000 W. Tendency was exhibited such that as plasma intensity increased, a growth speed of a thin film increased, surface roughness was small, and a dielectric constant increased (data is not shown). Therefore, intensity of 1,000 W or more is not excluded. Also, if plasma intensity is low, a thickness or surface roughness of a thin film may be controlled by increasing deposition time. Also, a dielectric constant may be changed according to the above. Therefore, 100 W or less is not excluded.

A temperature, a pressure, a flow rate of the first gas, a flow rate of the second gas, and plasma intensity of an optimal reactor are factors which affect one another. Therefore, it is natural that even though one parameter exhibits an optimal value at a specific value when other values are fixed, if other parameters are controlled, its absolute value may be changed.

The present disclosure confirms properties of an amorphous hydrocarbon thin film of which high dielectric properties have not been known until now and is for utilizing it as a high dielectric film. Those skilled in the art may easily implement to change the conditions and make a design so as to have optimal properties including a desired thickness, dielectric constant, and desired surface roughness according to use of a high dielectric film to be used and designs of other components.

Another example of the present disclosure relates to a semiconductor device including a high dielectric film. The high dielectric film may be a gate insulation film which needs for example, a high-k dielectric. An example of a semiconductor device of the present disclosure may be a memory device or a logic device. A high dielectric film of the present disclosure may apply as an insulation film of not only a thin film transistor but also a capacitor. That is, it may apply as an interlayer insulation film in a semiconductor-metal or metal-metal stack structure in a Metal-Insulator-Semiconductor (MIS) device or a Metal-Insulator-Metal (MIM) device.

As the above, a high dielectric film according to the present disclosure has a significantly higher dielectric value than that of not only SiO₂ but also conventional Hf- or Zr-based oxides, has a very low leakage current, and exhibits high dielectric strength. Accordingly, it may apply to a semiconductor of 10 nm nodes or less to exhibit more excellent performance.

Also, a high dielectric film of the present disclosure is easy to be grown in a desired thickness on a semiconductor or a metal substrate. Therefore, if it is directly deposited on a substrate, a transfer process is not needed, and thus a semiconductor device of which an interfacial property is excellent may be manufactured. Also, if it is grown and is transferred on a metal substrate, a dielectric film may be formed regardless of a type of a substrate. Therefore, it may apply to a flexible device which is weak to heat.

### BRIEF DESCRIPTION OF THE DRAWINGS

FIG. 1 is schematic diagrams and TEM images of carbon-based thin films synthesized at various deposition temperatures.

FIG. 2 is Raman spectra of carbon-based thin films synthesized at various deposition temperatures.

FIG. 3 is EELS spectra of carbon-based thin films synthesized at various deposition temperatures.

FIG. 4 is XPS spectra and EXAFS spectra of amorphous hydrocarbon thin films synthesized according to an example of the present disclosure.

FIG. 5 is FTIR spectra of an amorphous hydrocarbon thin films synthesized according to an example of the present disclosure.

FIG. 6 is secondary ion mass spectrometry results of amorphous hydrocarbon thin films synthesized according to an example of the present disclosure.

FIG. 7 is a schematic diagram of a MIS device including a high dielectric film according to an example of the present disclosure.

FIG. 8 is a graph illustrating an electrical properties of high dielectric films synthesized at various deposition temperatures.

FIG. 9 is of high dielectric films synthesized at various hydrocarbon gas flow rates.

FIG. 10 is AFM images of a high dielectric film according to an example of the present disclosure.

FIG. 11 is a C-V curve of a MIS device including a high dielectric film according to an example of the present disclosure.

### DETAILED DESCRIPTION

Hereinafter, referring to accompanied examples, the present disclosure is more specifically described. However, these examples are only examples for easily explaining a content and range of the technical spirit of the present disclosure and the technical range of the present disclosure is not limited or changed by the examples. Based on these examples, it is natural that various variations and changes are possible for those skilled in the art within a range of the technical spirit of the present disclosure.

### EXAMPLES

### Example 1: Manufacture of a Hydrocarbon Thin Film According to a Deposition Temperature

Under conditions below, a hydrocarbon thin film was deposited on a Si wafer or a Si/SiO₂/Ag (200 nm) substrate using a CH₄ gas and a hydrogen gas by Inductively-Coupled Plasma Chemical Vapor Deposition (ICP CVD). Specifically, 1 sccm of a CH₄ gas and 100 sccm of a mixture gas(10% of hydrogen) of hydrogen and Ar were injected into a reactor, wherein a pressure was fixed at 1 Torr, and plasma power was fixed at 600 W.

At deposition temperatures of 50° C., 400° C., 700° C., or 950° C., a thin film was grown for 5 minutes to manufacture a hydrocarbon thin film. A thin film deposited at 950° C. was deposited on a copper substrate to grow graphene.

For comparison, graphite was oxidized on chemical solution using a Hummer method and was peeled off to manufacture a graphene oxide thin film.

### Example 2: Evaluation of Properties of a Hydrocarbon Thin Film

1) Analysis of a Transmission Electron Microscope Image and a Raman Spectrum

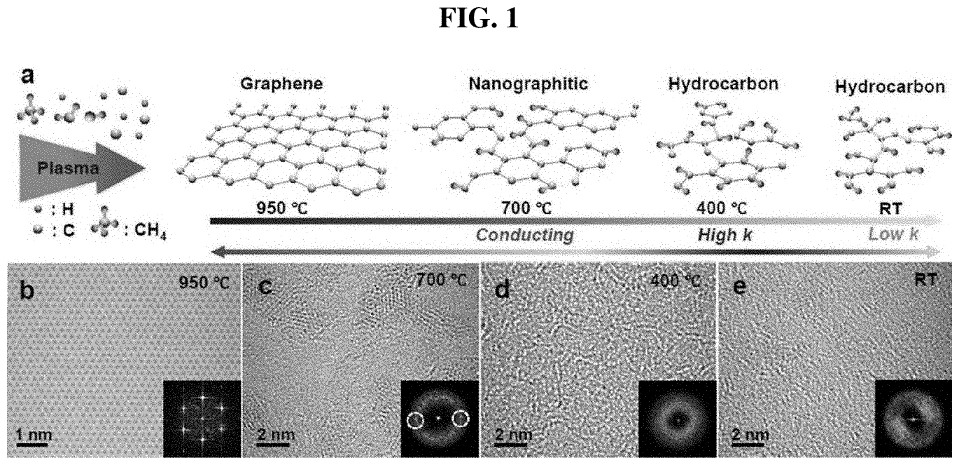

In Example 1, the hydrocarbon thin films grown according to the deposition temperatures were confirmed by an Aberration-corrected Transmission Electron Microscope (TEM) (Titan G2 Cube 60-300 kV, FEI), and results thereof were shown in FIG. 1.

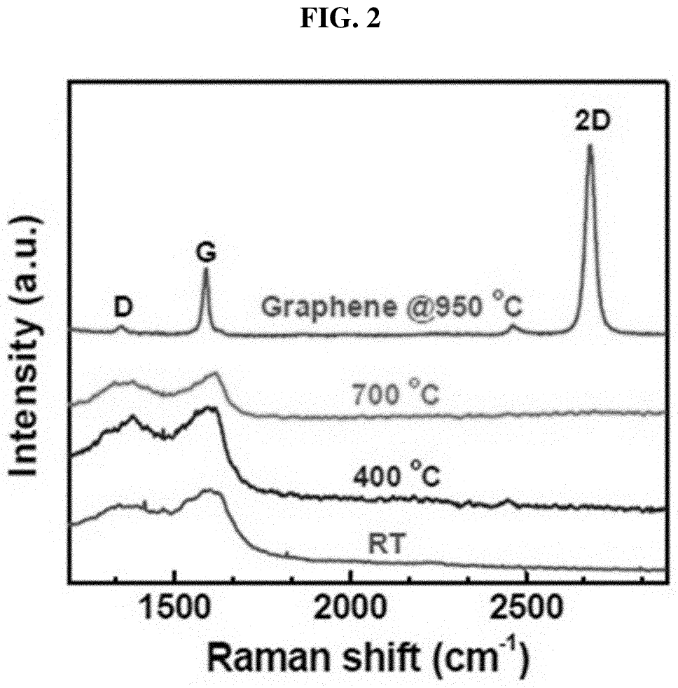

b of FIG. 1 is a TEM image of the hydrocarbon thin film deposited at 950° C. and shows that carbon atoms have a highly aligned hexagonal arrangement. An internal drawing illustrates a fast Fourier transformed (FFT) digital diffractogram and shows a hexagonal pattern, which is a typical property of high-quality graphene. Also, in a Raman spectrum of FIG. 2, I_{2D}/I_{G} exhibits a high value of about 3, and maximum half breadth of a 2D peak is small as 32 cm⁻¹, so that it could be confirmed that a high-quality graphene thin film was formed in comparative Example 1.

A thin film of which a deposition temperature was 700° C. showed Nanographite morphology where nanocrystals of hexagonal lattices were partially present within an amorphous matrix(c of FIG. 1). FFT shows a diffused ring shape having dark dots (shown as a circle). An interval of dots is 0.246 nm and it corresponds to carbon allotrope hexagonite.

When a deposition temperature was more lowered to 400° C. or 50° C., a thin film lost a nano crystallinity and exhibited an amorphous structure, and showed a halo FFT pattern(d and e of FIG. 1).

All of hydrocarbon thin films of which a deposition temperature is 700° C. or less do not exhibit a meaningful peak at a region of 2000 cm⁻¹ or more in a Raman spectrum shown in FIG. 2.

2) Analysis of an EELS Spectrum

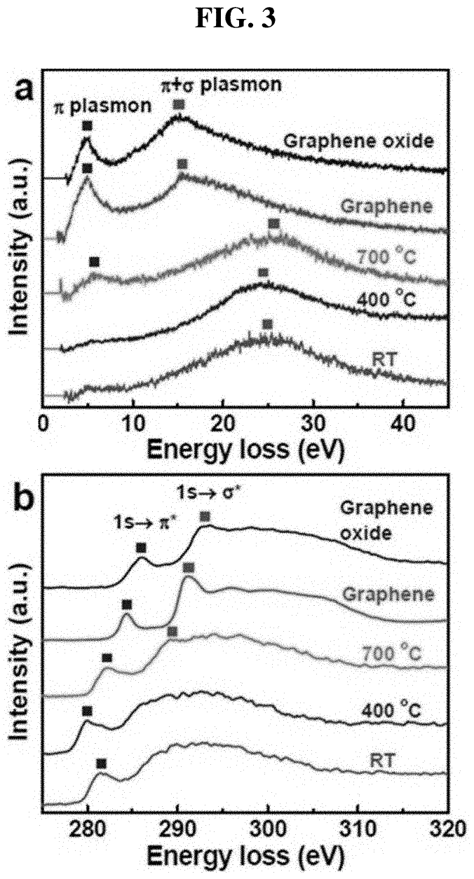

Using an Electron Energy-Loss Spectroscopy (EELS) device(Gatan Quantum 965 dual), an EELS spectrum was measured with respect to each of thin films manufactured in Example 1. For comparison, an EELS spectrum was also measured with respect to the graphene oxide thin film manufactured by oxidizing graphite in chemical solution using a Hummer method and peeling off it. a and b of FIG. 3 are EELS spectra of a low-loss region and a carbon K-edge region, respectively, wherein bonding aspects of hydrocarbon thin films according to deposition temperatures may be confirmed.

In a of FIG. 3, a graphene thin film showed two characteristic peaks, wherein a strong peak of 5 eV is a π plasmon peak related to a π→π* transition due to a sp² bond of carbon, and a broad peak around 15.5 eV is a (π+σ) plasmon peak. A position of the (π+σ) plasmon peak is in proportion to density of a valence electron, i.e., mass density of a carbon thin film. Compared to graphene thin film grown at 950° C., intensity of the n plasmon peak was significantly reduced on a thin film of which a deposition temperature was lowered to 700° C. Its result matched with that of a TEM image showing that Nanocrystalline hexagonite having a sp² bond was present within an amorphous matrix. As a deposition temperature is more lowered, only a (π+σ) plasmon peak is observed on thin films grown at 400° C. and 50° C. respectively. On thin films grown at a temperature of 700° C. or less, energy of a (π+σ) plasmon peak was 25.0 eV, 24.5 eV, and 25.8 eV, respectively, so that it was about 5 eV lower than that of a carbon thin film containing many sp³ bonds. Accordingly, it was implied that a ratio of sp³ bonds was very low. It assumes that the reason that energy on a thin film manufactured at 700° C. exhibits a relatively large value is that a crystalline state having high density is contained.

Presence of a n bond within a thin film may be also confirmed in an EELS spectrum of a carbon K-edge region shown in b of FIG. 3. On a thin film manufactured at 50° C. and 400° C., a first peak is observed at 281 eV, and it corresponds to a transition(1s→π*) from a is state to a π* state over a Fermi level. Based on the fact that a strong peak is observed on a relevant region, it may be confirmed that many sp² bonds are present within an amorphous thin film. A second peak is very broadly observed in a region of 290˜305 eV, and it corresponds to a 1s→σ* transition. When a deposition temperature increased to 700° C., a first peak was observed at ˜289.5 eV, so that it could be known that an energy band was narrowed due to nanocrystallization. This peak was more definitely observed in graphene manufactured at 950° C. According to an EELS spectrum, thin films manufactured at 50° C. and 400° C. were very similar with an amorphous hydrocarbon conventionally reported by J. Fink et. al. (Physical Review B, 30, 4713-4718 (1984)). On the contrary, an EELS spectrum of graphene oxides showed a very different aspect compared to hydrocarbon.

3) Analysis of XPS and EXAFS Spectra

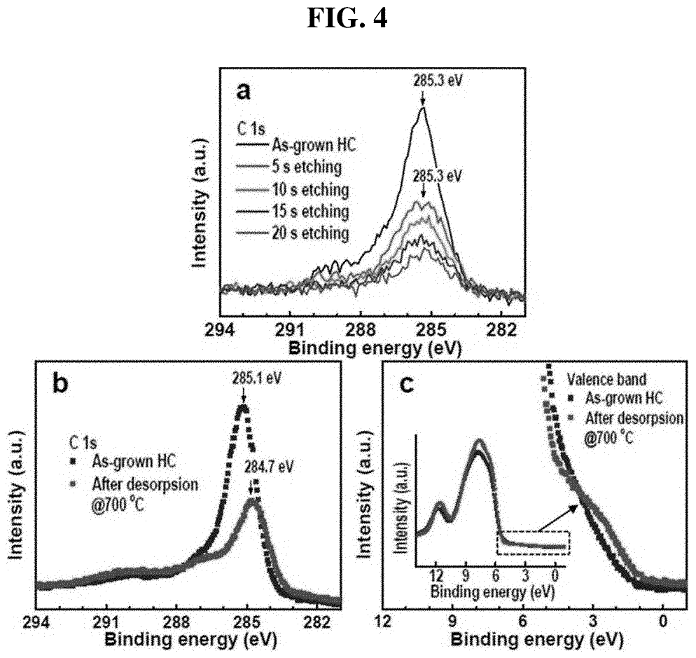

A chemical bond characteristic of a hydrocarbon thin film manufactured at 400° C. was confirmed by X-ray Photoelectron Spectroscopy(XPS) and an Extended X-ray Absorption Fine Structure(EXAFS). a of FIG. 4 is a XPS spectrum measured by using MultiLab 2000(Thermo Fisher Scientific) equipment with respect to a thin film manufactured at 400° C. and a thin film formed by etching it with argon plasma of 1 keV intensity for 5˜20 seconds. As confirmed in a of FIG. 4, 285.3 eV corresponding to aliphatic hydrocarbon CₓH_{y} was observed on the XPS spectrum of the hydrocarbon thin film. Despite etching by using Ar⁺ plasma, a position of the relevant peak was not changed, and thus it could be confirmed that a composition of the hydrocarbon thin film was uniform. Despite not additionally illustrating, a position of a peak shifts from 285.0 eV to 284.4 eV according to etching of a surface on a XPS spectrum of a graphene thin film. Various types of hydrocarbon may be absorbed on a graphene surface exposed in the air. As a result, high bonding energy of 285.0 eV is shown. According to etching, if hydrocarbon of the surface is removed, 284.4 eV, which is bonding energy of graphene itself is shown.

b of FIG. 4 is an EXAFS spectrum of a 1s core level, and c is an EXAFS spectrum around a fermi level. In b of FIG. 4, a strong peak of 285.1 eV corresponds to a peak of 285.3 eV of an XPS spectrum. To confirm that much hydrogen was contained in a hydrocarbon thin film, after manufacturing a thin film, it was heat-treated at 700° C. in-situ. After heat treatment, it was shown that a position of a peak was red-shifted to 284.7 eV and hydrogen was desorbed from aliphatic hydrocarbon CₓH_{y}. As a result, density of a diffused state of a desorbed specimen increased. As confirmed in c of FIG. 4, it was shown that intensity of a region around a fermi level increased.

4) Secondary Ion Mass Spectroscopy

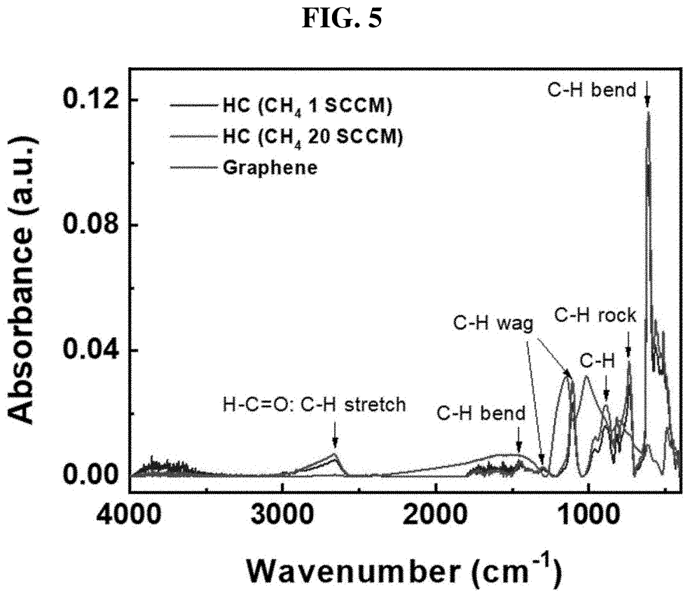

A spectrum of etching time of 0 second to 8 seconds was obtained while etching a hydrocarbon thin film grown at a deposition temperature of 200° C. to 400° C. according to a method of Example 1, using secondary-ion mass spectrometry(SIMS) equipment (TOF.SIMS M6, IONTOF GmbH) under a high-degree vacuum at room temperature. Its result was illustrated in FIG. 5.

In FIG. 5, it could be confirmed that a ratio(H/C) of relative intensity of hydrogen versus carbon within a hydrocarbon thin film corresponded to 2˜30. On a SIMS spectrum of a thin film, intensity of H/C was affected by a deposition temperature of the thin film, wherein tendency was shown such that when a deposition temperature increased from 200° C., H/C intensity increased and thus the highest value was exhibited at about 250˜300° C., and when a temperature increased more, it was lowered again. This implies a concentration of hydrogen contained within a thin film is determined by a deposition temperature.

There was no great difference in H/C intensity of a thin film according to etching time. Therefore, it could be confirmed that a composition of a hydrocarbon thin film was uniform identically to the XPS result.

5) Spectroscopic Analysis

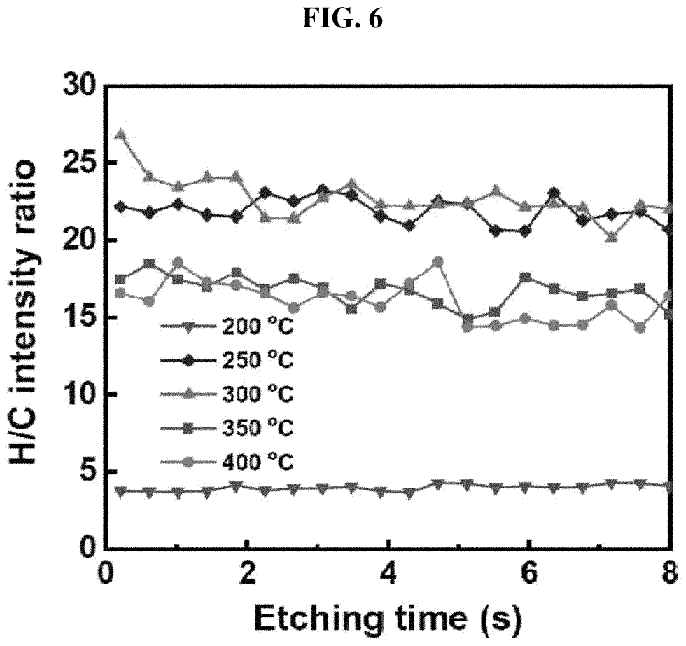

Via spectroscopic analysis of a graphene thin film and a hydrocarbon thin film grown at 400° C., a C—H bond was confirmed. FIG. 6 shows a FRIR spectrum of a thin film grown at a deposition temperature of 400° C. of Example 1. A peak corresponding to C—H stretching of a 2500˜3000 cm⁻¹ region which was not observed in graphene and a peak corresponding to C—H banding of a 500˜1200 cm⁻¹ region were observed. Thus, it could be confirmed again that a C—H bond was formed.

### Example 3: Evaluation of Electrical Properties of a Hydrocarbon Thin Film

1) Electrical Properties According to a Deposition Temperature of a Hydrocarbon Thin Film

A MIS device having a structure of FIG. 5 using a hydrocarbon thin film as a dielectric layer according to the present disclosure was manufactured, and an electrical property of the hydrocarbon thin film was evaluated. The hydrocarbon thin film was directly grown on a substrate or it was deposited on catalyst metal, and then it was transferred to manufacture a MIS device.

More specifically, in order to be directly grown on Si 100 wafer, the Si 100 wafer was immersed in 10% of hydrofluoric acid solution. After removing a SiO₂ natural oxide film, it was washed. After inserting the washed substrate into a ICP CVD reactor, the thin film of hydrocarbon was deposited for 30 minutes according to the conditions described in Example 1 except additionally noted conditions. For transfer of the hydrocarbon thin film, after inserting a Si/SiO₂/Ag(200 nm) substrate into an ICV CVD reactor, the hydrocarbon thin film was deposited for 5 minutes in the same condition as that of the direct growth. After the deposited hydrocarbon thin film was spin-coated with PMMA, it was soaked in FeCl₃ aqueous solution to etch an Ag catalyst layer. Accordingly, a hydrocarbon/PMMA film was separated. The separated hydrocarbon/PMMA film was transferred on a Si 100 wafer, and then it was soaked in acetone to remove PMMA. An AFM image of hydrocarbon grown on an Ag catalyst layer or a Si wafer itself where the Ag catalyst layer was not present showed to have a surface which was uniform, did not have a pin hole, and was smooth.

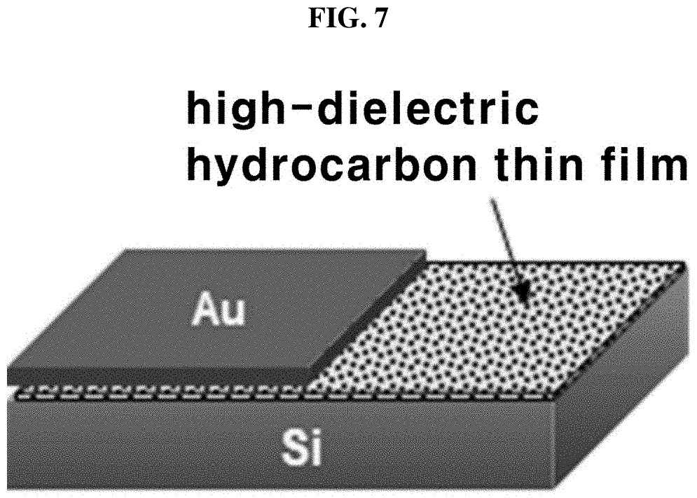

As described above, an Au electrode having a diameter of 100 μm was formed on the hydrocarbon thin film which was directly grown or transferred on the Si 100 wafer to manufacture a MIS device having a structure of FIG. 7. In Table 1, a thickness and rms roughness of the hydrocarbon thin film, and a dielectric constant in the MIS device measured from the sectional TEM and AFM(Asylum Research, MFP-3D) of the hydrocarbon thin film used in the MIS device were exhibited.

TABLE 1

| | Deposition | Thin Film | rms | Dielectric |
|---|---|---|---|---|
| | Temperature | Thickness | Roughness | Constant |
| Substrate | (° C.) | (nm) | (nm) | (k) |
| Si | 400 | 6.5 | 1.61 nm | 13 |
| Si | 350 | 5.0 | | 90 |
| Si | 300 | 3.1 | | 82 |
| Si | 250 | 2.4 | | 66 |
| Si | 200 | 2.6 | | 19 |
| Si/SiO₂/Ag | 600 | 51.0 | | 30 |
| Si/SiO₂/Ag | 500 | 63.0 | | 61 |
| Si/SiO₂/Ag | 400 | 46.0 | 3.06 nm | 42 |
| Si/SiO₂/Ag | 300 | 9.0 | | 11 |
| Si/SiO₂/Ag | 200 | 3.3 | | 6 |
| Si/SiO₂/Ag | 100 | 1.2 | | 0.4 |

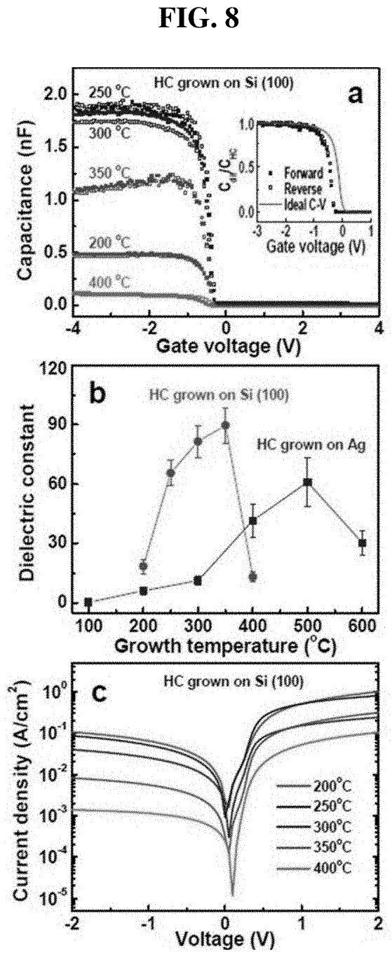

FIG. 8 are graphs showing electrical properties measured with respect to the manufactured MIS device. a of FIG. 8 is a C-V curve of the hydrocarbon thin film directly grown on a silicon wafer, wherein ● is a value measured from −4 V to 4 V, and o is a value measured from +4 V to −4 V. The most important characteristic in the C-V curve is that hysteresis is less than 5 mV nearly close to 0 in a C-V loop with respect to all specimens. This satisfies a standard (<30 mV) of a high-k gate dielectric. The fact that a transition from accumulation and depletion is fast and hysteresis is very small means that charge density of a thin film and charge density trapped in a thin film and a Si interference is very small. Compared to the above, the MIS device manufactured with the hydrocarbon thin film, which was grown on catalyst metal and then was transferred on a Si substrate exhibited significant hysteresis, wherein transfer from accumulation and depletion was relatively slow (not shown). It is assumed that this is due to deterioration of interfacial properties in a transfer process, and contamination in an etching process of an Ag catalyst thin film during transfer. As confirmed in the internal drawing of a of FIG. 8, compared to the fact that the C-V curve exhibited an ideal shape, flat band voltage of the hydrocarbon thin film slightly shifted to − voltage due to a fixed positive charge. Differences of the flat band voltage among specimen were not great and all of them belonged to a range of −0.3˜0.4 V.

A dielectric constant(k) of the hydrocarbon thin film may be calculated from the following equation.

Cₘₐₓ=ε_{(HC)}/t_{(HC)}

Here, Cₘₐₓ is an integrated capacitance, ε_{(HC)} is permittivity of the hydrocarbon thin film, and t_{(HC)} is a thickness of the hydrocarbon thin film.

B of FIG. 8 is a graph showing dielectric constants of thin films manufactured at each temperature. Permittivity of the hydrocarbon thin film directly grown on a silicon wafer was maximum 90 and was very excellent compared to 20-30 of a dielectric constant of Hf- and Zr-based oxides known as high dielectric gate oxides. As a growth temperature of a thin film increased, a dielectric constant gradually increased and a maximum value of 90 was exhibited at 350° C. When a temperature more increased and arrived at 400° C., permittivity was lowered to 13. Tendency about a thin film growth temperature of the hydrocarbon thin film transferred on a Si wafer was similar with that of the hydrocarbon thin film directly grown. As a deposition temperature increased, a dielectric constant also gradually increased and a maximum value of 61 is arrived at 500° C. Thereafter, when a temperature more increased and arrived at 600° C., it reduced again. It seems that in a hydrocarbon thin film deposited at a low temperature, dipole moments chaotically arranged offset one another, and thus a relatively low k value is exhibited, and as a temperature increases, structuralization of carbon skeleton construction increases and dipole moments also increase, and thus a dielectric constant increases. If arriving at a critical temperature or more, it is difficult to capture hydrogen and hydrocarbon in a dangling bond, and thus a hydrocarbon structure is broken and a characteristic as a high-k dielectric is lost.

One of important characteristics as a high-k dielectric is that density of a leakage current is to be low and an insulation level is to be high. c of FIG. 8 is a I-V curve, wherein thin films manufactured at 300° C. and 350° C. of which dielectric constants are 82 and 90, respectively had a leakage current of 0.15 A/cm² at 1V with respect to equivalent oxide film thicknesses of 0.15 and 0.2 nm. A leakage current exhibits the lowest value on a thin film deposited at 400° C., wherein its thickness is about 6.5 nm and the relevant thin film is the thickest among thin films. All specimens did not exhibit a breakdown phenomenon up to 5V, so that it could be known that an insulation level had high values as at least 5 MV/Cm or more, and generally 10 MV/Cm or more. These leakage currents and insulation levels are at least identical to or more excellent than high-k oxides recently reported.

### Example 4: Evaluation of Properties of a Hydrocarbon Thin Film According to a Composition of a Reaction Gas

Except that a deposition temperature was fixed at 350° C. and an injecting speed of a CH₄ gas was changed to 1˜20 sccm, a hydrocarbon thin film was manufactured by the same process as that of manufacturing the hydrocarbon thin film of Example 1. Using the thin film, the same MIS as that of Example 3 was manufactured, wherein an electric property of the thin film was evaluated together with a physical property thereof.

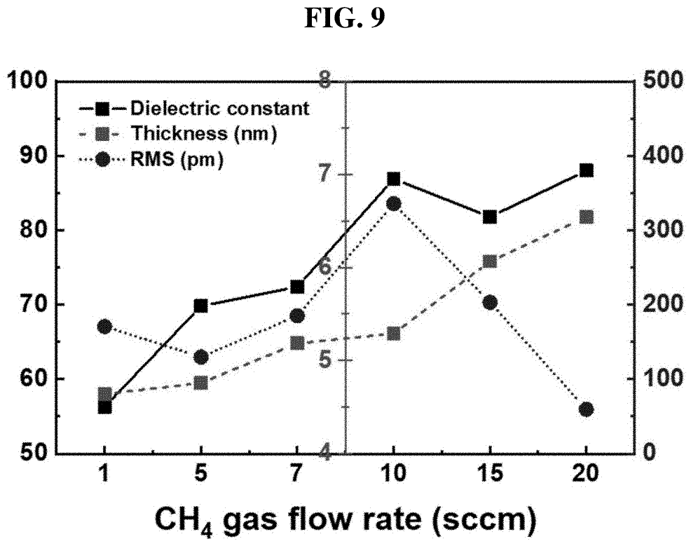

FIG. 9 is a graph showing its result, wherein it may be confirmed that a ratio of a hydrocarbon gas and hydrogen affects an electric property and a physical property of the manufactured hydrocarbon thin film. In particular, as predictable, as supply of a hydrocarbon gas increased, a growth speed of the thin film increased, and thus when a ratio of a generated CH₄ gas was the highest, a thickness of the thin film was the thickest. Roughness of the thin film is one of important factors which determine an interfacial property upon manufacturing a device. As a ratio of the CH₄ gas increased, roughness gradually increased but when it increased more than 10 sccm, a surface roughness was significantly reduced. In the case of 20 sccm, the smoothest thin film was formed. A dielectric constant of the thin film also exhibited tendency of gradually increasing as a ratio of a CH₄ gas increases.

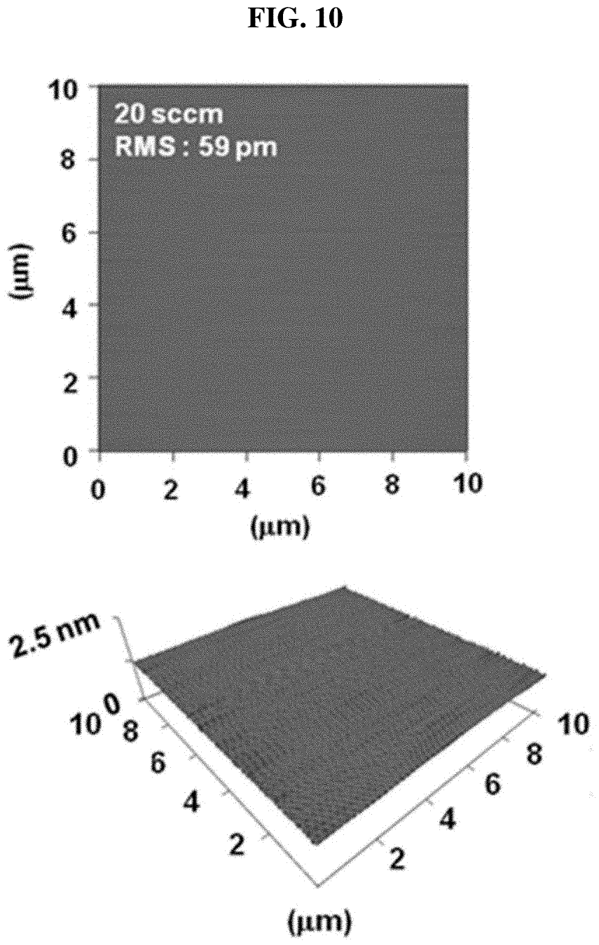

FIG. 10 is an AFM image of a dielectric film deposited with a reaction gas of 100 sccm of an Ar gas including 20 sccm of a CH₄ gas and 10% of a H₂ gas under conditions of 350° C., 600 W, and 1 torr. It was confirmed that a film on which a pin hole was not present and which was very uniform was grown. A rms surface roughness is very low as 0.059 nm, so that it may excellently applies to a device such as MIS or MIM. A dielectric constant of the thin film gradually increased as plasma power increased.

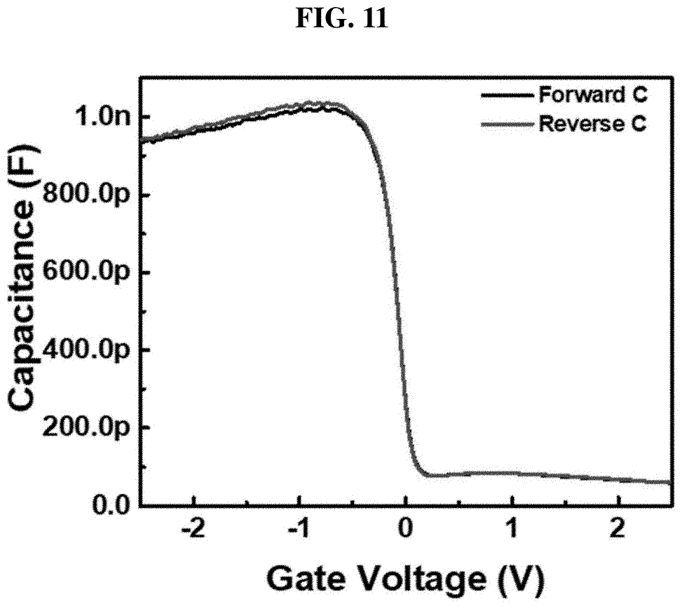

FIG. 11 is a C-V curve of an MIS device manufactured by using the high dielectric film. On the C-V curve, there were nearly no C-V hysteresis and flat-band voltage shift. Accordingly, it could be confirmed that an excellent MIS structure where there was nearly no defect on an interface of a hydrocarbon thin film was formed.

1. A high dielectric film, comprising: amorphous hydrocarbon of which a dielectric constant is 10 or more.

2. The high dielectric film of claim 1, wherein a leakage current of the high dielectric film is 1 A/cm² or less, and an insulation level is 1 MV/cm or more.

3. The high dielectric film of claim 1, wherein rms surface roughness of the high dielectric film is 20 nm or less.

4. A high dielectric film manufactured by comprising steps of:
(A) positioning a substrate within a plasma reactor;
(B) injecting a first gas including a hydrocarbon gas and a second gas including a hydrogen gas into the reactor; and
(C) generating plasma within the reactor, thereby growing a hydrocarbon thin film, wherein
any one of a temperature, a pressure, a flow rate of the first gas, a flow rate of the second gas, and plasma intensity of the reactor is controlled in order that the hydrocarbon thin film is the hydrocarbon thin film having a dielectric constant of 10 or more.

5. The high dielectric film of claim 4, wherein the reactor is the reactor for plasma-assisted chemical vapor deposition, inductively coupled plasma chemical vapor deposition, or electron cyclotron resonance chemical vapor deposition.

6. The high dielectric film of claim 4, wherein a temperature of the reactor is controlled in a range of 20° C.˜700° C.

7. The high dielectric film of claim 4, wherein flow rates of the first gas and the second gas are controlled in order that a volume ratio of the hydrocarbon gas of the first gas and the hydrogen gas of the second gas is 100:1˜1:50.

8. The high dielectric film of claim 4, wherein a pressure of the reactor is controlled in a range of 0.1 Torr˜10 Torr.

9. The high dielectric film of claim 4, wherein the plasma intensity is controlled in a range of 100 W˜1,000 W.

10. The high dielectric film of claim 4, wherein the substrate is a semiconductor substrate or a metal substrate.

11. The high dielectric film of claim 10, wherein it is grown and is transferred on the metal substrate.

12. A semiconductor device comprising the high dielectric film of claim 1.

13. A capacitor comprising the high dielectric film of claim 1.
